(19) United States
(12) Patent Application Publication
(10) Pub. No.: US 2025/0023570 A1
(43) Pub. Date: Jan. 16, 2025

(54) ELECTRONIC CONTROL DEVICE

(71) Applicant: NXP B.V., Eindhoven (NL)

(72) Inventors: Javier Mauricio Velandia Torres, Graz (AT); Sebastien Darfeuille, Graz (AT); Patrick Dominik Gsöls, Kirchberg an der Raab (AT)

(21) Appl. No.: 18/766,186

(22) Filed: Jul. 8, 2024

(30) Foreign Application Priority Data
Jul. 13, 2023 (EP) 23185274.0

(51) Int. Cl. H03L 1/02; H03B 5/12; H03L 7/099; H03L 7/18

(52) U.S. Cl. CPC H03L 1/022; H03B 5/124; H03L 7/099; H03L 7/18; H03B 2200/004

(57) ABSTRACT

Electronic control device (200), comprising:
a first input (201) for a control voltage (Vₜᵤₙₑ) of a voltage controlled device (200);
a second input (202) for a reference control voltage (Vₜᵤₙₑ₀) of the voltage controlled device (200); and
an output (203), wherein
the electronic control device (200) is configured to provide a bias current change (ΔI_{B}) via the output (203) to the voltage controlled device (200) in order to maintain a level of the control voltage (Vₜᵤₙₑ) inside a specified range.

### TECHNICAL FIELD

The present disclosure relates to an electronic control device. Furthermore, the present disclosure relates to a method of operating an electronic control device.

### BACKGROUND

Voltage-Controlled Oscillators (LC-VCOs) are state of the art in high performance PLLs because of their low-phase noise properties. The frequency of the VCO is fine-tuned by the PLL acting on a voltage-controlled capacitor. The input is known as control voltage Vₜᵤₙₑ. Occasionally, the VCO also integrates coarse tunability with digital-controlled capacitors to extend the operation range. Such digitally-controlled capacitors are calibrated before the

PLL can start controlling and fine-tuning the frequency. Due to limited range of control voltage to correct frequency drift in the LC-VCO, applications running with a locked PLL are often restricted in their ability to accommodate temperature drift or long continuous operation without a recalibration of the digitally-controlled capacitors (if they exist). Indeed, a temperature drift causes a change in the oscillator's output frequency when keeping the control voltage constant in open-loop configuration, whereas in closed-loop configuration the loop tries to counteract the frequency change by adjusting the control voltage as far as the PLL's supply (VDD) range allows. Therefore, the tuning voltage turns out to be the bottleneck, especially as VDD room becomes lower with more advanced CMOS technology nodes, leaving the loop less room for counteraction. Consequently, strong temperature changes of the already locked PLL can rapidly bring the PLL out of lock.

Using a second point injection in the oscillator to compensate the drift via additional varactors is possible but it results in additional parasitics in the LC tank which can limit the tuning range, limiting the maximum operating frequency, increasing the power or impacting the overall noise.

Conventional bias-current based compensation techniques use a combination of PTAT/CTAT (proportional to absolute temperature/complementary to absolute temperature) currents fed to a VCO's bias current node for counteracting the temperature-induced frequency drift. This kind of compensation solely relies on the current's temperature coefficient. Hence, the temperature, which can be seen as a second reference input (besides the tuning voltage), acts on a system in open-loop configuration. Any frequency error that may occur due to improper bias current adaption can therefore only be compensated by the main loop of the PLL (via tuning voltage adaption).

US 9 413 366 B2 discloses apparatus and methods for phase-locked loops with temperature compensated calibration voltage.

US 8 803 616 B2 discloses temperature compensation and coarse tune bank switches in a low phase noise VCO.

US 8 466 750 B2 discloses VCO utilizing an auxiliary varactor with temperature dependent bias.

### SUMMARY

A first aspect of the present disclosure is directed to an electronic control device, comprising:
a first input for a control voltage of a voltage controlled device;
a second input for a reference control voltage of the voltage controlled device; and
an output, wherein
the electronic control device is configured to provide a bias current change via the output to the voltage controlled device in order to maintain a level of the control voltage inside a specified range.

A further aspect of the present disclosure is directed to a method of operating an electronic control device, comprising the steps:
receiving a control voltage and a reference control voltage of a voltage controlled device; and
providing a bias current change to the voltage controlled device in such a way, that a level of the control voltage is kept inside a specified range.

In this way, by means of the proposed electronic control device and the proposed method, the voltage controlled device is at least partially controlled by means of a bias current. Advantageously, no additional control elements are required, which in effect results in an effective temperature desensitization of the voltage controlled device. No needs exist to design the voltage controlled device in order to incorporate the control characteristics by means of the electronic control device.

In one or more embodiments, the electronic control device is configured to minimize a difference between the control voltages.

In one or more embodiments, the control voltage is implemented within a first control loop of the voltage controlled device, wherein the electronic control device is implemented within an additional control loop of the voltage controlled device. In this way, a loop based arrangement is implemented, which can easily be controlled.

In one or more embodiments, the control loops have different time constants, wherein the first control loop has a fast behavior to track changes affecting a frequency synthesizer, wherein the additional control loop has a slow behavior in order to follow temperature variations. In this context, a “fast behavior” is typically in the microsecond range and a “slow behavior” is typically in the range of milliseconds or more.

In one or more embodiments, the electronic control device is configured to correct a temperature drift of the voltage controlled device by adapting the control voltage.

In one or more embodiments, the electronic control device is configured to maintain the control voltage in a dependency of an electric supply voltage. In this way, a specified operational characteristics of the electronic control device is supported.

In one or more embodiments, the electronic control device is configured to maintain the control voltage inside a specified range with respect to the electric supply voltage.

In one or more embodiments, the electronic control device is configured to control an LC-oscillator-based frequency synthesizer.

In one or more embodiments, the electronic control device comprises the following blocks, which are functionally serially coupled with each other: difference amplifier, low pass filter, Voltage-To-Current (V2I)-converter. By means of the low pass filter, control loop characteristics (e.g. with respect to time constants) may be designed properly.

In one or more embodiments, the electronic control device is configured to artificially generate an additional VCO-gain by measuring a tuning voltage shift, converting the voltage shift into a current and feeding the resulting bias current change to a voltage controlled oscillator of the voltage controlled device.

In one or more embodiments, the electronic control device is configured to derive, with the VCO's bias current sensitivity a transconductance, needed in the voltage-to-current converter in order to implement the temperature-compensation/artificial VCO gain.

### BRIEF DESCRIPTION OF DRAWINGS

The above discussion/summary is not intended to describe each embodiment or every implementation of the present disclosure. The drawings and detailed description that follow also exemplify various embodiments. The aspects defined above and further aspects of the present disclosure are apparent from the examples of embodiment to be described herein-after with reference to the appended drawings, which are explained with reference to the examples of embodiment. However, the disclosure is not limited to the examples of embodiment.

All illustrations in the drawings are schematical. It is noted that in different figures, similar or identical elements or features are provided with the same reference signs or with reference signs that are different from the corresponding reference signs only within the first digit. In order to avoid unnecessary repetitions, elements or features which have already been elucidated with respect to a previously described embodiment are not elucidated again at a later position of the description.

Various example embodiments may be more completely understood in consideration of the following detailed description in connection with the accompanying drawings, in which:

FIG. 1 shows a conventional control loop-based frequency synthesizer;

FIG. 2 is a diagram illustrating a control voltage to control a frequency in dependence of temperature;

FIG. 3 are diagrams showing the parameters: temperature, frequency and control voltage of the conventional system in FIG. 1;

FIG. 4 is a diagram with an embodiment of a proposed electronic control device;

FIG. 5 is a diagram showing a LC-VCO frequency characteristic curve with control voltage and bias current dependency;

FIG. 6 are diagrams showing the parameters: temperature, frequency and control voltage with the proposed method in FIG. 4; and

FIG. 7 is a diagram with a flow of the proposed method.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration and not limitation.

### DESCRIPTION OF EMBODIMENTS

Aspects of the present disclosure are believed to be applicable to a variety of different types of devices, apparatuses, systems and methods involving voltage controlled devices formed as frequency synthesizers. While not necessarily so limited, various aspects may be appreciated through the following discussion of non-limiting examples which use exemplary contexts.

In the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same reference signs may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

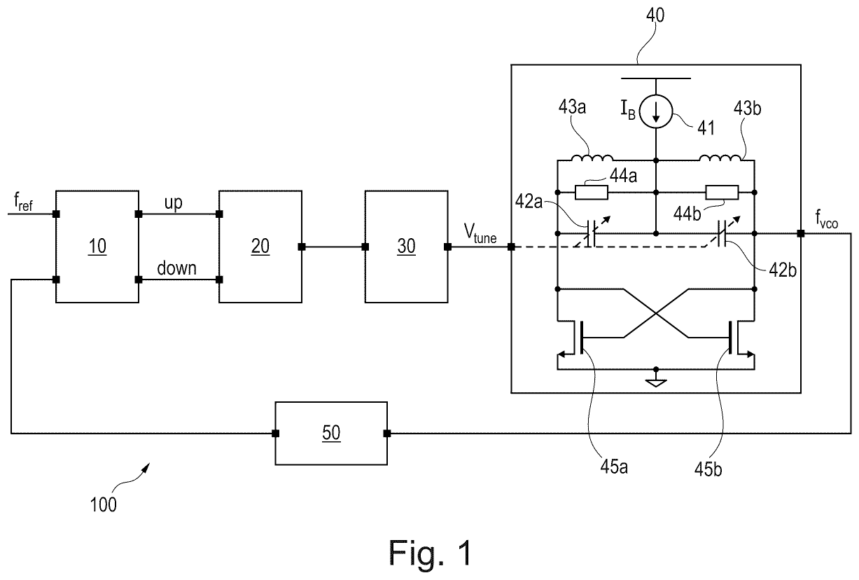

Almost every system which relies on clock-signals uses PLLs at some point for frequency synthesis, skew suppression, jitter reduction or clock recovery. In modern transceiver/receiver systems there exists a need of frequency synthesizers, implemented e.g. as Phase Locked Loops (PLLs) with LC-VCOs for low noise, as exemplary shown in FIG. 1. One recognizes a block diagram of a conventional voltage controlled device 100 formed as a frequency synthesizer with a main control loop. The frequency synthesizer comprises a phase frequency detector 10 which receives a reference clock signal f_{ref} and which provides signals “up”, “down” to a downstream charge pump 20. The charge pump 20 provides an output signal to a loop filter 30, which integrates input electric charges from the charge pump 20 and which provides an electric control voltage Vₜᵤₙₑ to a voltage controlled oscillator 40 (LC-VCO) with a bias current source 41. The voltage controlled oscillator 40 comprises variable capacitors (varactors) 42a, 42b, which are controlled via the control voltage Vₜᵤₙₑ.

Moreover, the voltage-controlled oscillator 40 comprises inductors 43a, 43b, transistors 45a, 45b and parasitic resistors 44a, 44b which are interconnected in a manner known per se. At an output of the voltage controlled oscillator 40 a signal with a frequency f_{VCO} is provided, which is supplied to a divider element 50 which provides a signal with a divided frequency f_{VCO} to a second input of the phase frequency detector 10. In this way, the frequency synthesizer is controlled by a main loop having the above mentioned components including a charge pump 20 (so called PLL type II-arrangement). Due to temperature variations and the temperature dependency of the elements of the LC-VCO the frequency f_{VCO} will vary depending on the temperature for a given fixed control voltage.

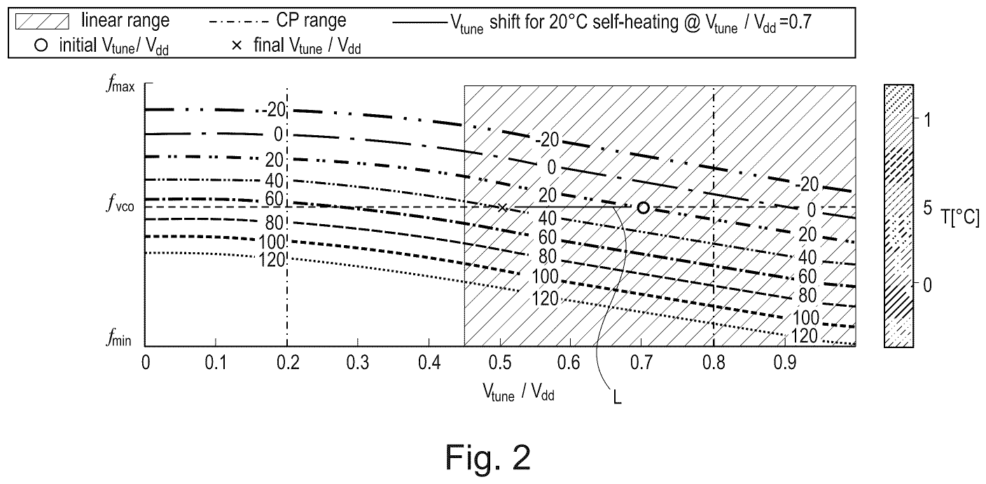

FIG. 2 depicts an example of a typical LC-VCO frequency tuning curve, where the varactors 42a, 42b are used for controlling the frequency f_{VCO} of the frequency synthesizer. In general, any type of MOS varactor 42a, 42b can be used, it may simply affect the polarity of the frequency gain which is then taken into account when connecting the other blocks of the frequency synthesizer. Due to the movement towards large SoCs in more advanced technology nodes the on-chip temperature gradients become larger and larger, causing a dramatic amount of temperature-induced frequency variation which go beyond what the control loop of the frequency synthesizer could compensate due to tuning voltage range limitations. This could, in a worst case scenario, result in an unlocked frequency synthesizer, meaning that a self-heating effect is that high that there is no longer an intersection between a line L (constant frequency line) and the frequency curves shown in FIG. 2.

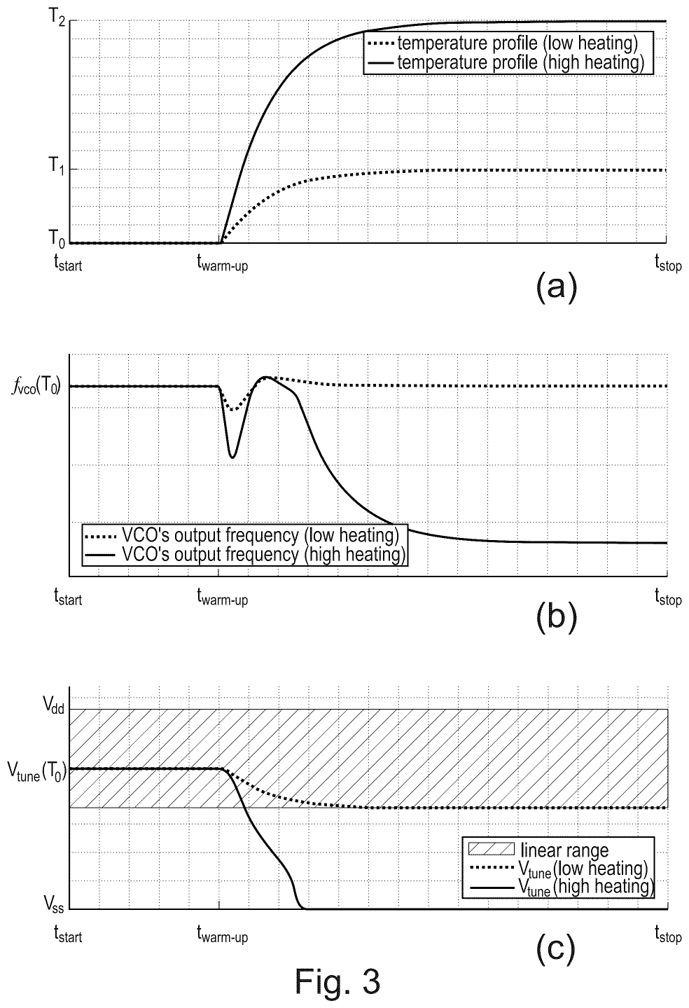

This effect becomes even more obvious in the time-domain as depicted in FIG. 3. An assumed temporal temperature profile is shown in FIG. 3A. For simplicity, the system is not experiencing any temperature change during start-up. At some point in time, the system starts to heat up, which leads to reduced VCO output frequency as shown in FIG. 3b and which the frequency synthesizer corrects by adjusting the electric control voltage Vₜᵤₙₑ. FIG. 3b shows two temporal courses of the frequency f_{VCO} for low heating (dotted curve) and high heating (solid curve). For noise reasons, LC-VCOs do have low VCO-gain K_{VCO}, which means that this correction process of the frequency synthesizer only works within a certain temperature range.

In comparison, FIG. 3c shows a transient tuning voltage reaction of the control loop of the frequency synthesizer, whereas FIG. 2 shows what happens with the control voltage Vₜᵤₙₑ in locked mode, when the temperature changes and the frequency of the voltage controlled oscillator 40 drifts away from the original calibration temperature (needed static voltage shift to keep locked condition). Eventually the voltage rails and the charge pump 20 cannot operate anymore. As a result, the frequency synthesizer goes out of lock and the application needs to recalibrate the VCO bands. The effect becomes stronger if the range for the control voltage Vₜᵤₙₑ is smaller like in modern advanced technology nodes. Since recalibration of the coarse-tuning capacitors (if they exist) in the voltage controlled oscillator 40 during online operation is in most cases not possible, because thereby one would create frequency jumps when switching capacitors on and off, it is proposed to implement an additional loop-based circuitry to compensate the temperature-induced frequency shift.

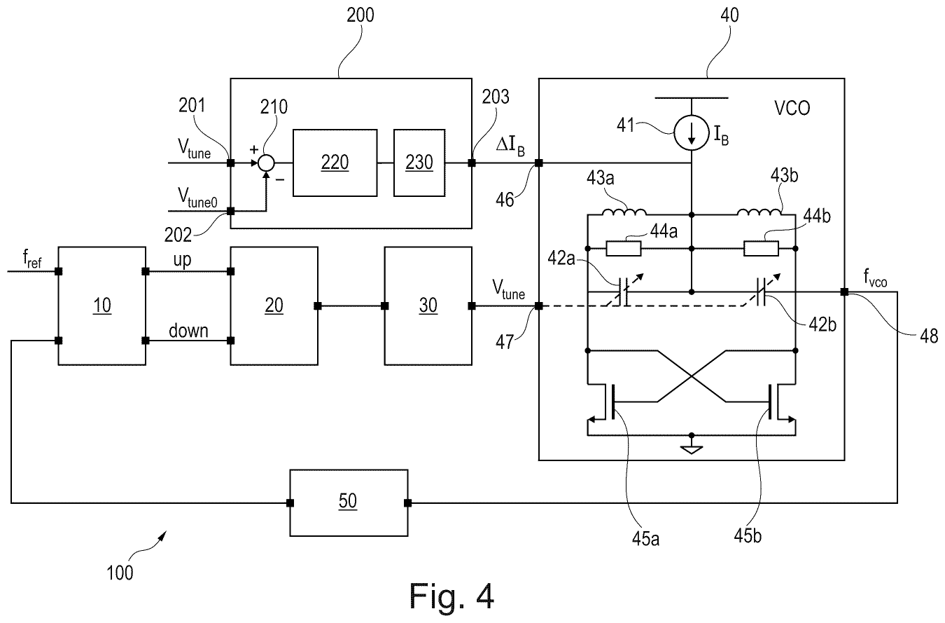

FIG. 4 presents an exemplary voltage controlled device 100 implemented as frequency synthesizer with a cross-coupled voltage controlled oscillator 40 and a proposed electronic control device 200 which is based on a bias-current adaption technique implemented with a V2I-converter (voltage-to-current converter) 230. With the proposed bias-current adaption technique it is possible to use an electric bias current I_{B} (VCO's bias current) as a second tuning point to control the oscillator frequency via a secondary slow loop inside the frequency synthesizer. It is well known that cross-coupled LC-VCOs do have a characteristic of a bias current dependent output frequency f_{VCO} and how compensation circuit parameters can be calculated in this context. Therefore, no more details are given in this respect. At the output 48 of the voltage controlled oscillator 40 a signal with a frequency f_{VCO} is provided, which is supplied to the divider element 50 which provides a signal with a divided frequency f_{VCO} to the second input of the phase frequency detector 10.

The two control loops have different time constants, wherein the first control loop has a fast behavior, typically in the range of microseconds, wherein the additional control loop has a slow behavior relative to the first loop in order to follow temperature variations (e.g. with time constants of milliseconds to seconds). In effect, the voltage controlled frequency synthesizer is controlled by a first control loop and additionally at least partially by means of the proposed electronic control device 200.

The proposed bias-current adaption technique by means of V2I-converter 230 is not limited to analog PLLs (like in FIG. 1) but it can also be applied to digital PLLs, where the control voltage Vₜᵤₙₑ is replaced by a digitalized control word and the voltage controlled-capacitor is replaced by a discrete capacitor array digitally-controlled by the control word. The electronic control device 200 comprises three main building blocks or stages, respecttively. A first stage is a difference amplifier 210, which compares the control voltage Vₜᵤₙₑ, which is supplied at a first input 201 of the electronic control device 200 and at a second input 47 of the voltage controlled oscillator 40 and which is dynamically adjusted by the main control loop of the frequency synthesizer, against the reference control voltage Vₜᵤₙₑ₀ used to (e.g. initially) calibrate the output frequency of the voltage controlled oscillator 40 for a specific temperature To. The reference control voltage Vₜᵤₙₑ₀ can be seen as a reference input to the electronic control device 200. In an ideal world the control voltage Vₜᵤₙₑ will perfectly converge to the reference control voltage Vₜᵤₙₑ₀, which is supplied at a second input 202 of the electronic control device 200 if everything is in steady-state.

Downstream of the difference amplifier 210 is a low-pass filter 220 which slows down the second control loop being implemented by means of the electronic control device 200. This additional time constant has multiple reasons.

Firstly, the second closed control loop should be robust against process variations. Furthermore, fast tuning voltage changes, which are not temperature-induced, shall not reflect on the VCO's bias current I_{B}. The electronic control device 200 shall be as transparent as possible, which means that it should ideally not change the PLL's open- and closed-loop characteristic. Lastly, the V2I converter 230 is responsible for converting a temperature-induced tuning voltage change ΔVₜᵤₙₑ into a corresponding bias current change ΔI_{B}, which is supplied at an output 203 of the electronic control device 200 and at a first input 46 of the voltage controlled oscillator 40. Possibilities for calculating the V2I-converter's transconductance Gₘ as such are well known.

In effect, the electronic control device 200 is configured to minimize a difference between the control voltages Vₜᵤₙₑ and Vₜᵤₙₑ₀.

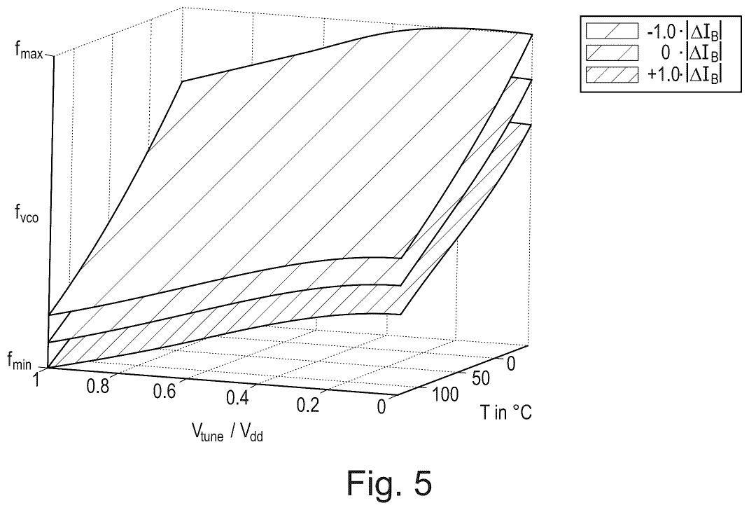

The ability to adjust the bias current I_{B} dynamically, practically results in the creation of a second control branch for the voltage controlled oscillator 40 which results in a three-dimensional VCO frequency characteristic curve, as exemplary shown in FIG. 5, which shows a LC-VCO frequency characteristic curve with tuning voltage and bias current dependency over temperature. The proposed electronic control device 200 exploits the temperature-induced tuning voltage shift ΔVₜᵤₙₑ and converts it into a proportional bias current change ΔI_{B}. An underlying idea is to artificially generate an additional VCO-gain K_{VCO}^{(comp)}. This can be done by measuring the tuning voltage shift ΔVₜᵤₙₑ, converting it into a current and feeding this current change to the LC-VCO. From a behavioral point of view one needs a voltage-to-current (V2I) converter 230 with a proper transconductance Gₘ.

The necessary transconductance Gₘ of the voltage-to-current converter 230, for a fully temperature compensated voltage controlled oscillator 40, is derived from the VCO's two-dimensional frequency curve, as depicted in FIG. 2. First, one needs to extract the maximum frequency shift caused within the VCO's temperature range:

$$Δ {f}_{vco}^{( max )} = max ( max ( {f}_{vco} ( T , {V}_{tune} ) ) - min ( {f}_{vco} ( T , {V}_{tune} ) ) ) \qquad ( 1 )$$

A full temperature compensation of the voltage-controlled device 100 is in most cases not necessary. Often it is enough if the VCO's sensitivity regarding temperature is reduced. Hence, one could simply set Δf_{vco}^{(max)} to a value which corresponds to a certain temperature range which is wanted to cover without having to recalibrate the voltage controlled oscillator 40.

Since frequency synthesizers formed as PLLs do have tuning voltage limitations, it should be taken into account how much the tuning voltage can be varied around the calibrated operating point at the reference voltage Vₜᵤₙₑ₀.

$$Δ {V}_{tune}^{( max )} = \{ \begin{matrix}{V}_{tune 0} - Δ {V}_{tune}^{( min )} , & sign ( \frac{{df}_{vco}}{dT} {\vert}_{{T}_{0} , {V}_{tune 0}} ) = sign ( \frac{{df}_{vco}}{{dV}_{tune}} {\vert}_{{T}_{0} , {V}_{tune 0}} ) \\ Δ {V}_{tune}^{( max )} - {V}_{tune 0} , & sign ( \frac{{df}_{vco}}{dT} {\vert}_{{T}_{0} , {V}_{tune 0}} ) \neq sign ( \frac{{df}_{vco}}{{dV}_{tune}} {\vert}_{{T}_{0} , {V}_{tune 0}} )\end{matrix} \qquad ( 2 )$$

With equations (1) and (2) one can calculate the temperature-compensation VCO gain K_{vco}^{(comp)} as

$${K}_{vco}^{( comp )} = sign ( \frac{{df}_{vco}}{{dV}_{tune}} {\vert}_{{T}_{0} , {V}_{tune 0}} ) \cdot \frac{Δ {f}_{max}}{Δ {V}_{tune}^{( max )}} . \qquad ( 3 )$$

From a change in the VCO's bias current I_{B} which leads to shifted frequency curves, it can be deduced how sensitive the VCO frequency is to changes in the bias current I_{B}. With the VCO's bias current sensitivity

$$\frac{{df}_{vco}}{{dI}_{B}}$$

(assuming constant sign for all current sensitivity values) and equation (3) one can derive the transconductance Gₘ needed in the voltage-to-current converter 230 in order to implement the proposed temperature-compensation/artificial VCO gain:

$${G}_{m} = {K}_{vco}^{( comp )} . {( sign ( \frac{{df}_{vco}}{{dI}_{B}} {\vert}_{{T}_{0} , {V}_{tune 0 , {I}_{B 0}}} ) \cdot min ( \vert \frac{{df}_{vco}}{{dI}_{B}} \vert ) )}^{- 1} \qquad ( 4 )$$

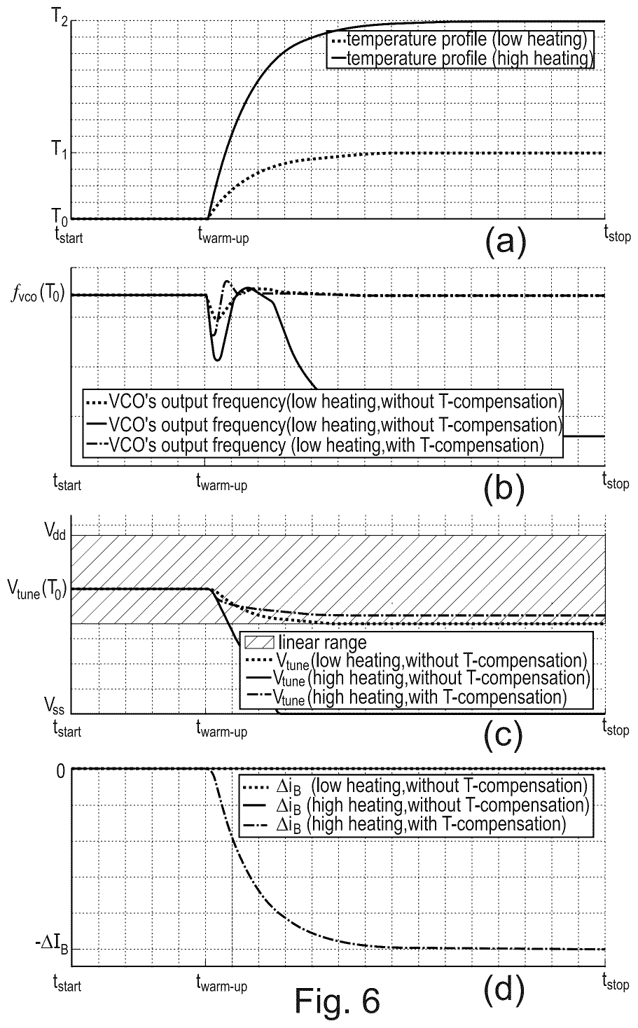

Transient plots shown in FIG. 6 visualize the action of the whole temperature desensitized frequency oscillator if it is exposed to low and high heating (see FIG. 6a). As visible from the VCO's output frequency f_{VCO} (see FIG. 6b), the frequency synthesizer can no longer maintain locked state without countermeasures if it is strongly heated (solid curve). This happens due to the tuning voltage limitation of the system (solid curve in FIG. 6c). In comparison, at low heating (dotted curve in FIG. 6c), correction via the electric control voltage Vₜᵤₙₑ is sufficient to obtain a locked frequency synthesizer.

The electronic control 200 provides sinks or sources current from the bias current node of the VCO (as shown in FIG. 6d), providing a locked PLL state by adjusting the output frequency (dashed curve in FIG. 6b) of the oscillator without reaching the limits of the tuning voltage Vₜᵤₙₑ (dashed curve in FIG. 6c).

In an embodiment, the electronic control device 200 may be configured to maintain the control voltage Vₜᵤₙₑ in a dependency of an electric supply voltage V_{dd}.

In an embodiment, the electronic control device 200 may be configured to maintain the control voltage Vₜᵤₙₑ inside a specified range with respect to the electric supply voltage V_{dd}.

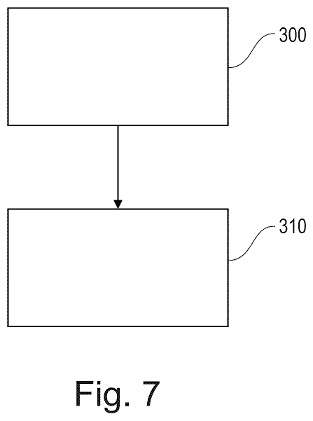

FIG. 7 shows a flow of a proposed method of operating an electronic control device 200.

In a step 300 a control voltage Vₜᵤₙₑ and a reference control voltage Vₜᵤₙₑ₀ of a voltage controlled device 100 are received.

In a step 310 a bias current change ΔI_{B} is provided to the voltage controlled device 100 in such a way, that a level of the control voltage Vₜᵤₙₑ is kept inside a specified range.

The proposed temperature compensation device exploits in its secondary control loop the properties of a closed-loop system. The higher the open-loop gain of the amplifiers used inside the difference amplifier stage of the electronic control device 200 are, the lower the remaining error, that has to be controlled by the control voltage Vₜᵤₙₑ in order to keep the VCO's output frequency stable.

The proposed electronic control device 200 can be easily added to existing PLLs without any change inside the sensitive oscillator core (LC-tank). The temperature compensation is done in a secondary slow control loop in a closed loop fashion in order to make it robust against process variations, and it is at the same time not very intrusive from a PLL topology perspective as this only comes as an add-on element to the existing circuit. The original building blocks do not require particular re-design and the main loop characteristics are not affected.

The proposed electronic control device can be used e.g. as part of any LC-VCO-based PLL that requires uninterrupted operation while in the presence of temperature variations that could be too large to handle just from the oscillator tuning voltage. UWB ICs are good candidates for that, but several other ICs especially in the field of wireless communications could also benefit from the proposed control device.

Summarizing, a temperature desensitization technique for RF LC-VCO based PLLs by controlling the oscillator biasing in closed loop is proposed, which allows the PLL to stay in lock over large temperature range, without the need to recalibrate the oscillator.

As another example, where the specification may make reference to a “first” type of structure, a “second” type of structure, where the adjectives “first” and “second” are not used to connote any description of the structure or to provide any substantive meaning; rather, such adjectives are merely used for English-language antecedence to differentiate one such similarly-named structure from another similarly-named structure.

Based upon the above discussion and illustrations, those skilled in the art will readily recognize, that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps.

It should be noted that the term “comprising” does not exclude other elements or steps and “a” or “an” does not exclude a plurality. Also elements described in association with different embodiments may be combined. It should also be noted, that reference signs in the claims should not be construed as limiting the scope of the claims.

It is noted that the embodiments above have been described with reference to different subject-matters. In particular, some embodiments may have been described with reference to method-type claims whereas other embodiments may have been described with reference to apparatus-type claims. However, a person skilled in the art will gather from the above that, unless otherwise indicated, in addition to any combination of features belonging to one type of subject-matter also any combination of features relating to different subject-matters, in particular a combination of features of the method-type claims and features of the apparatus-type claims, is considered to be disclosed with this document.

It has to be noted that embodiments have been described with reference to different subject matters. In particular, some embodiments have been described with reference to method type claims whereas other embodiments have been described with reference to apparatus type claims. However, a person skilled in the art will gather from the above and the following description that, unless other notified, in addition to any combination of features belonging to one type of subject matter also any combination between features relating to different subject matters, in particular between features of the method type claims and features of the apparatus type claims is considered as to be disclosed with this application.

### REFERENCE SIGNS

10 phase frequency detector
20 charge pump
30 loop filter
40 voltage controlled oscillator (VCO)
41 bias current source
42a, 42b I-MOS varactor
43a, 43b inductor
44a, 44b parasitic resistor
45a, 45b transistor
46 1^{st} input
47 2^{nd} input
48 output
50 divider element
100 voltage controlled device
200 electronic control device
201 1^{st} input
202 2^{nd} input
203 output
300, 310 method steps
f_{ref} reference frequency
f_{VCO} oscillator frequency
L line
ΔI_{B} bias current change
I_{B} bias current
V_{dd} supply voltage
Vₜᵤₙₑ control voltage
Vₜᵤₙₑ₀ reference control voltage

1-12. (canceled)

13. An electronic control device, comprising:
a first input configured to receive a control voltage of a voltage controlled oscillator (VCO);
a second input configured to receive a reference control voltage of the VCO; and
an output;
wherein the electronic control device is configured to adjust a bias current of the VCO by providing a signal at the output in response to a temperature change in order to maintain a level of the control voltage inside a specified range.

14. The electronic control device of claim 13, wherein the electronic control device is configured to minimize a difference between the control voltage and the reference control voltage.

15. The electronic control device of claim 13, wherein the control voltage is adjusted in a first control loop of the VCO, wherein the electronic control device forms part of and additional control loop of the VCO.

16. The electronic control device of claim 15, wherein the control loops have different time constants, wherein the first control loop has a fast behavior to track changes affecting a frequency synthesizer, wherein the additional control loop has a slow behavior in order to follow temperature variations.

17. The electronic control device of claim 13, wherein the electronic control device is configured to correct a temperature drift of the voltage controlled oscillator by adapting the control voltage.

18. The electronic control device of claim 13, wherein the electronic control device is configured to maintain the control voltage in a dependency of an electric supply voltage.

19. The electronic control device of claim 18, wherein the electronic control device is configured to maintain the control voltage inside a specified range with respect to the electric supply voltage.

20. The electronic control device of claim 13, wherein the electronic control device is configured to control an LC-oscillator based frequency synthesizer.

21. The electronic control device of claim 13, comprising the following components, connected in series: a difference amplifier; a low pass filter connected to an output of the difference amplifier; and a Voltage-to-Current (V2I) converter connected to an output of the low pass filter.

22. The electronic control device of claim 21, wherein the control device is configured to artificially generate an additional VCO-gain by measuring a tuning voltage shift, converting the voltage shift into a current and feeding the resulting bias current change to the VCO.

23. The electronic control device of claim 22, wherein the control device is configured to derive, with the VCO's bias current sensitivity a transconductance (Gₘ) needed in the voltage-to-current converter in order to implement the temperature-compensation/artificial VCO gain.

24. Electronic control device, comprising:
a first input configured to receive a control voltage of a voltage controlled oscillator (VCO);
a second input configured to receive a reference control voltage of the VCO; and
an output;
wherein the electronic control device is configured to provide a signal at the output to adjust a bias current of the VCO in order to maintain a level of the control voltage inside a specified range;
wherein the electronic control device is configured to control an LC-oscillator based frequency synthesizer.

25. A method for operating an electronic control device, the method comprising:
receiving a control voltage and a reference control voltage of a voltage controlled oscillator (VCO); and
providing a temperature-induced bias current change to the voltage controlled oscillator such that a level of the control voltage is kept inside a specified range.

26. The method of claim 25, further comprising:
minimizing a difference between the control voltage and the reference control voltage.

27. The method of claim 25, further comprising:
using a first control loop having a fast behavior to track changes affecting a frequency synthesizer, and
using an additional control loop having a slow behavior to follow temperature variations.

28. The method of claim 25, further comprising:
correcting a temperature drift of the VCO by adapting the control voltage.

29. The method of claim 25, further comprising:
controlling an LC-oscillator based frequency synthesizer.
